(19) United States
(12) Patent Application Publication
(10) Pub. No.: US 2013/0134267 A1
(43) Pub. Date: May 30, 2013

(54) Apparatus for Supporting Tablet Personal Computers

(71) Applicant: JAN-BAN LIU, Taichung City (TW)

(72) Inventor: JAN-BAN LIU, Taichung City (TW)

(21) Appl. No.: 13/307,000

(22) Filed: Nov. 30, 2011

(51) Int. Cl. H05K 7/00

(52) U.S. Cl. 248/122.1

(57) ABSTRACT

An apparatus, for supporting tablet personal computers, comprises a main frame, a connection member, a support leg, and a base. The main frame is provided with a coupling means at a center thereof. The connection member, which is provided with a coupling means corresponding to the coupling means of the main frame and is attached with an auxiliary holding means at a back thereof, is coupled to a back of the main frame. The support leg has an upper portion at one end thereof for engaging with the connection member, and a lower portion at the other end thereof for detachably and pivotally coupled to the base. Thereby, a tablet personal computer can be accommodated to the main frame to allow the computer to have a feature of multiple directions and multiple angles and to be operated more easily and comfortably.

### (a) TECHNICAL FIELD OF THE INVENTION

The present invention relates to an apparatus for supporting tablet personal computers, and more particularly to an apparatus that can support a tablet personal computer at multiple directions and multiple angles to allow the computer to be operated more easily and comfortably.

### (b) DESCRIPTION OF THE PRIOR ART

With the advance of electronic technology, mobile phones, computers, hardware disks, and other electronic devices have become more and more slim. For example, a typical desktop computer, which may include a chassis having a main board therein, a monitor, and a keyboard, is large in size and not easy to be carried out. To facilitate the portability of a computer, a notebook computer was developed. Recently, for making a computer even more slim, compact, and easy to carry, a tablet-sized personal computer; known as a tablet PC, has emerged on the market, which integrates a touchscreen as an input device to make the whole body even smaller.

However, in use, a tablet personal computer is often laid on a table, so that users should keep their heads down about 90 degrees, for reading the contents shown on the screen of the tablet personal computer and operating the computer. This posture may cause the users to feel uncomfortable in their necks and shoulders, and may bring eyestrain. To reduce the above problem, the users may hold tablet personal computers in their hands for reading information on the screens thereof. However, this condition will also result in additional burdens on their hands, which is not a good way of using a tablet personal computer.

In view of the foregoing, the applicant has contrived an apparatus that can support the tablet personal computers at multiple angles, so that the users can use them with ease and comfort.

### SUMMARY OF THE INVENTION

The primary object of the present invention is to provide an apparatus, for supporting tablet personal computers, which can be oriented in multiple directions and multiple angles.

To achieve the above object, the apparatus may comprise a main frame, a connection member, a support leg, and a base. The main frame is provided with a coupling means at a center thereof. The connection member, which is provided with a coupling means corresponding to the coupling means of the main frame and is attached with an auxiliary holding means at a back thereof, is coupled to a back of the main frame. The support leg has an upper portion at one end thereof for engaging with the connection member, and a lower portion at the other end thereof for detachably and pivotally coupled to the base. Thereby, a tablet personal computer can be accommodated to the main frame to allow the computer to have a feature of multiple directions and multiple angles and to be operated more easily and comfortably

According to one aspect of the present invention, the main frame may include two lower bar extending downwardly and one upper bar extending upwardly, each lower bar being provided with a recessed portion at its end for holding a corner of a tablet personal computer, the upper bar being provided with a movable retaining member.

According to another aspect of the present invention, the movable retaining member is provided with two bosses respectively at two sides thereof, the upper bar is provided with two rail portions respectively at two sides thereof.

According to a further aspect of the present invention, the upper portion of the support leg is provided with two engagement protrusions at two sides of its top end, the connection member is provided with two engagement portions, corresponding to the two engagement protrusions, at two sides of the coupling means of the connection member.

According to a still further aspect of the present invention, the connection member is provided with two lugs respectively at two opposing sides of the back thereof, to attach the auxiliary holding means.

According to a still further aspect of the present invention, the auxiliary holding means is a Velcro tape, a looping strap, a rubber band, an elastic cord, or the like.

According to a still further aspect of the present invention, the base defines a recess including a hole therein, through which a fastening means can insert through a pad to couple with a seat that is provided with a pivot portion on its top.

Other objects, advantages, and novel features of the present invention will become more apparent from the following detailed description when taken in conjunction with the accompanying drawings.

### BRIEF DESCRIPTION OF THE DRAWINGS

FIG. 1 is a 3-dimensional view of one embodiment of the present invention.

FIG. 2 is an exploded view of the embodiment.

FIG. 3 is a schematic view of the embodiment, which shows a forward or backward angle adjustment for the support leg of the embodiment.

FIG. 4 is a schematic view of the embodiment, which shows a use of a tablet personal computer.

FIG. 5 is a schematic view of the embodiment, which shows a lateral angle adjustment for the main frame of the embodiment.

FIG. 6 is a partially enlarged view of the embodiment, which shows the connection member and the support leg of the embodiment.

FIG. 7 is a schematic view of the embodiment, which shows another use of the embodiment.

### DETAILED DESCRIPTION OF THE PREFERRED EMBODIMENTS

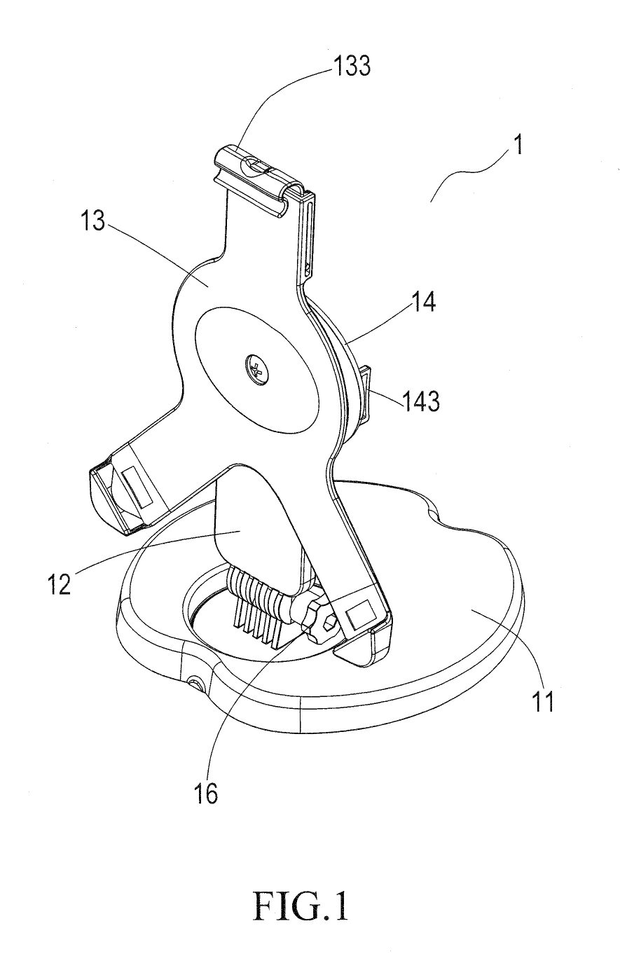

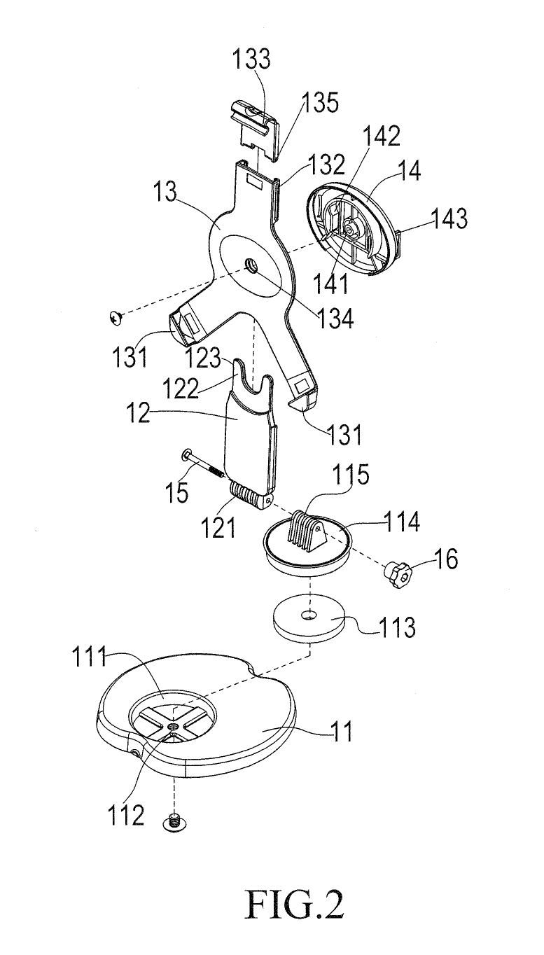

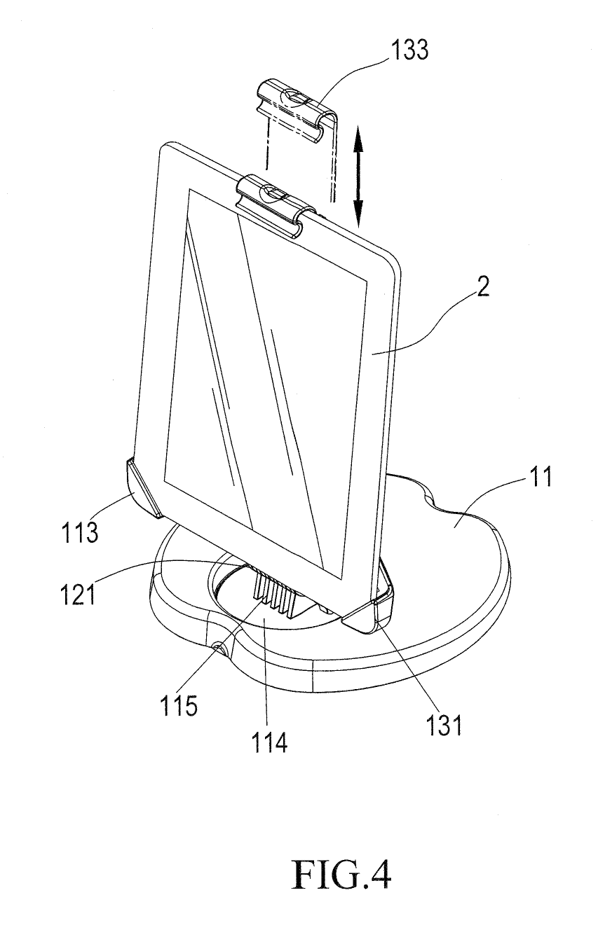

Turning now to FIGS. 1 and 2, one embodiment of an apparatus for supporting tablet personal computers, according to the present invention, is illustrated and indicated by reference numeral 1. The apparatus 1 generally comprises a main frame 13, a connection member 14, a support leg 12, and a base 11. The main frame 13 is used for accommodating a tablet personal computer (see FIG. 4). The main frame 13 is provided with a coupling means, which may be implemented by a screw and a central hole 134 defined at a center of the main frame 13. The main frame 13 has three bars extending from a central portion thereof, which include two lower bars extending downwardly and one upper bar extending upwardly. Each of the lower bars is provided with a recessed portion 131, for holding a corner of a tablet personal computer, at its end. The upper bar is provided with two rail portions 132 respectively at two sides thereof, for being movably assembled with a movable retaining member 133, which is provided with two bosses 135 respectively at two sides thereof and is formed with a resilient clip at a top thereof.

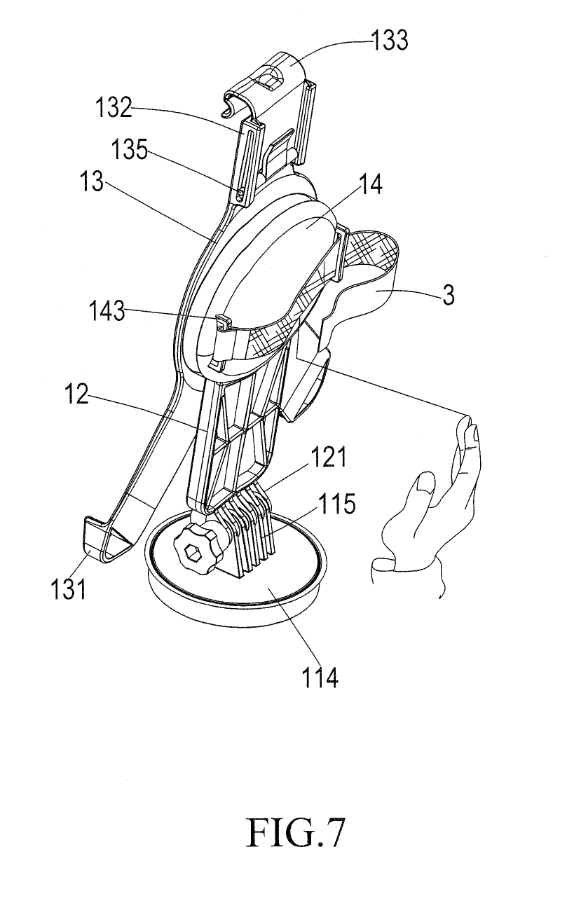

The connection member 14 is provided with a coupling means, which may be a cylindrical hollow post 141, corresponding to the coupling means of the main frame 13, so that the connection member 14 can be coupled to a back of the main frame 13 by using the screw of the coupling means of the main frame 13 and the cylindrical hollow post 141 of the connection member 14. As shown, there are some ribs formed on the connection member 14 around the cylindrical hollow post 141, among which there are two ribs, located across the cylindrical hollow post 141, each being provided with an engagement portion 142 at its top end. Also, in this embodiment, the connection member 14 can be attached with an auxiliary holding means 3 (see FIG. 7) at a back thereof. In more detail, the connection member 14 can be provided with two lugs 143 respectively at two opposing sides of the back of the connection member 14, to attach the auxiliary holding means 3.

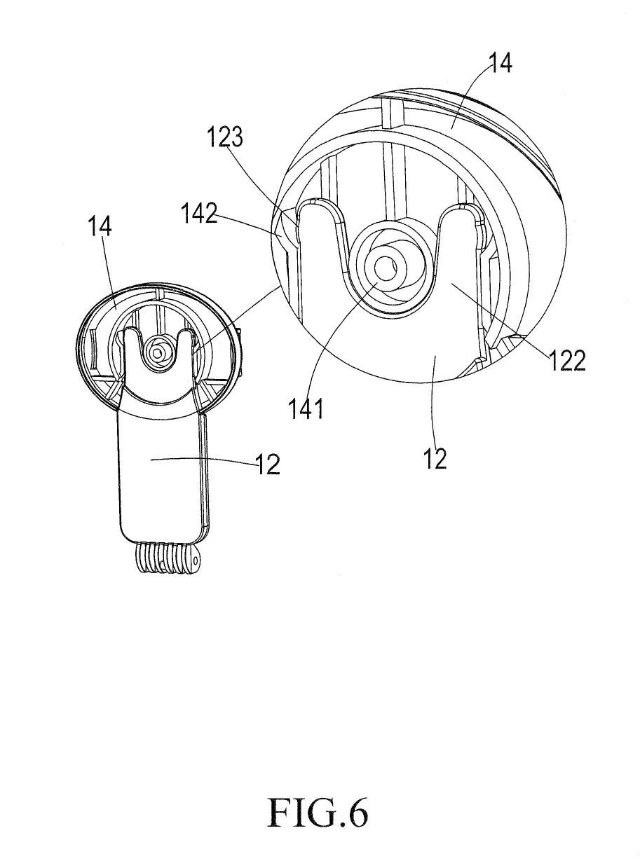

The support leg 12 has an upper portion 122, which has a flat surface indented from the main part of the support leg 12 and the appearance of which is generally U-shaped, at one end thereof. The upper portion 122 has two engagement protrusions 123 respectively at two sides of its top end. As shown in FIG. 6, the upper portion 122 can be inserted into the connection member 14 to be located under the cylindrical hollow post 141, in which the engagement protrusions 123 of the upper portion 122 of the support leg 12 can engage with the engagement portions 142 of the ribs of the connection member 14. Also, the support leg 12 has a lower portion 121 at the other end thereof, which can be detachably and pivotally coupled to a seat 114 that is provided with a pivot portion 115 on its top and defines a hole on its bottom, by using a bolt 15 and a nut 16. The base 11 defines a recess 111 therein, which includes a hole 112 at a center thereof. A pad 113 having a through hole can be placed in the recess 111 of the base 11. A fastening means, such as a screw, can be inserted through the hole 112 of the base 11 and the hole of the pad 113 to reach the hole of the seat 114, to allow the pad 113 and the seat 114 to be coupled together.

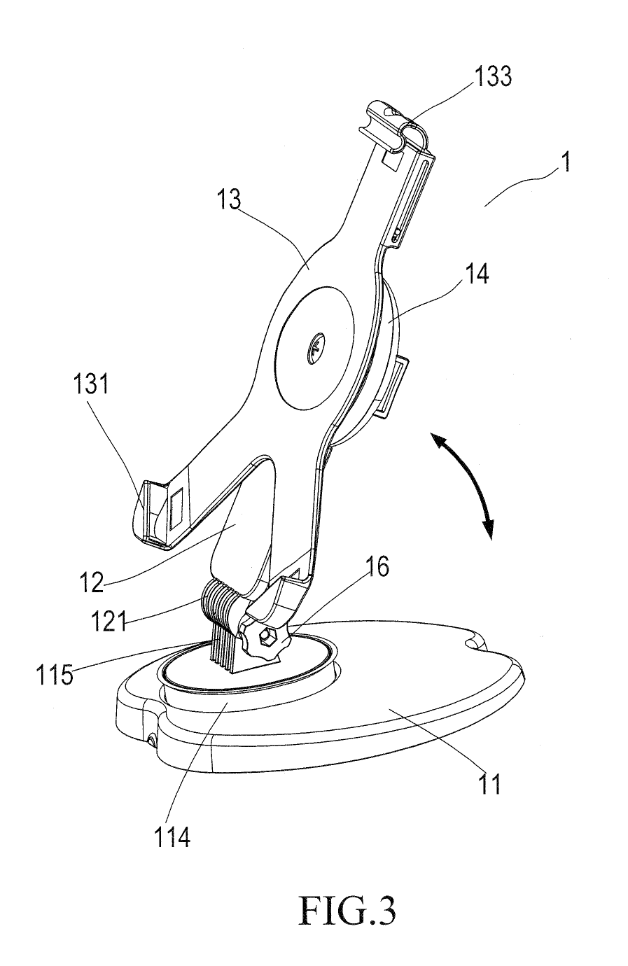

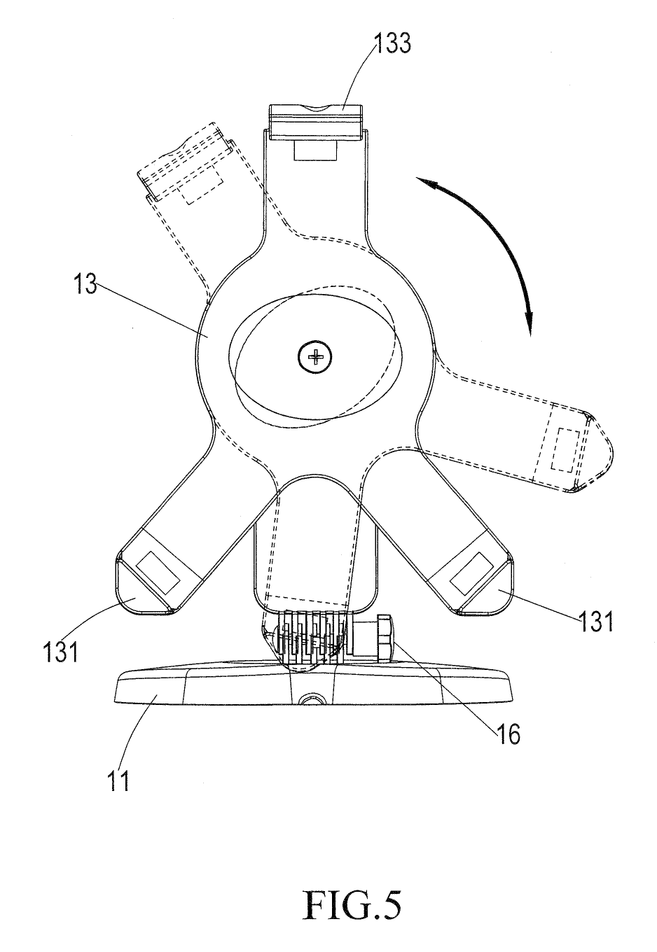

As shown in FIG. 3, the apparatus of the present invention employs the base 11, which has a large area, to allow the support leg 12 and the main frame 13 to stand up firmly. Furthermore, since the lower portion 121 of the support leg 12 is detachably and pivotally coupled to the pivotal portion 115 of the seat 114, the support leg 12 can be operated to have a rotation, in a range of about 180 degrees, with respect to its lower portion 121 or the pivot portion 115 of the seat 114. Thereby, the main frame 13 can be adjusted to an angle suitable for a user. In use, as shown in FIG. 4, the movable retaining member 133 can be moved upward, and then a tablet personal computer 2 can be accommodated to the main frame 13 to allow the two bottom corners of the tablet personal computer 2 to be put in the recessed portions 131 of the main frame 13. Thereafter, the movable retaining member 133 can be moved downward to allow the resilient clip at its top to clip a top edge of the tablet personal tablet computer 2, so that the tablet personal computer 2 can be firmly supported on the apparatus of the present invention. With such design, the tablet personal computer 2 can be rotated forward or backward about the pivot portion 115 of the seat 114, and the tablet personal computer 2 can be rotated laterally about the central hole 134 of the main frame 13, in a range of 360 degrees, as shown in FIG. 5. In addition, the lugs 143, provided at the back of the connection member 14, can be employed to attach the auxiliary holding means 3, which can be a Velcro tape, a looping strap, a rubber band, an elastic cord, or the like. In this embodiment, as shown in FIG. 7, the auxiliary holding means 3 is a Velcro tape, which may facilitate the hand of a user to hold the apparatus of the present invention.

Although the present invention has been described with a certain degree of particularity, it is understood that the present disclosure is made by way of example only and the combination and arrangement of parts may be resorted to without departing from the spirit and scope of the invention hereinafter claimed.

I claim:

1. An apparatus for supporting tablet personal computers, comprising:
a main frame for accommodating a tablet personal computer, said main frame being provided with a coupling means at a center thereof;
a connection member being provided with a coupling means corresponding to said coupling means of said main frame, and being attached with an auxiliary holding means at a back thereof; said connection member being coupled to a back of said main frame; and
a support leg having an upper portion at one end thereof for engaging with said connection member and a lower portion at the other end thereof for detachably and pivotally coupled to a base.

2. An apparatus for supporting tablet personal computers as claimed in claim 1, wherein said main frame has two lower bar extending downwardly and one upper bar extending upwardly, each said lower bar being provided with a recessed portion at its end for holding a corner of a tablet personal computer, said upper bar being provided with a movable retaining member.

3. An apparatus for supporting tablet personal computers as claimed in claim 2, wherein said movable retaining member is provided with two bosses respectively at two sides thereof, said upper bar is provided with two rail portions respectively at two sides thereof.

4. An apparatus for supporting tablet personal computers as claimed in claim 1, wherein said upper portion of said support leg is provided with two engagement protrusions at two sides of its top end, the connection member is provided with two engagement portions, corresponding to two said engagement protrusions, at two sides of said coupling means of said connection member.

5. An apparatus for supporting tablet personal computers as claimed in claim 1, wherein said connection member is provided with two lugs respectively at two opposing sides of the back thereof, to attach said auxiliary holding means.

6. An apparatus for supporting tablet personal computers as claimed in claim 1, wherein said auxiliary holding means is a Velcro tape, a looping strap, a rubber band, an elastic cord, or the like.

7. An apparatus for supporting tablet personal computers as claimed in claim 1, wherein said base defines a recess including a hole therein, through which a fastening means can insert through a pad to couple with a seat that is provided with a pivot portion on its top.
